(19) United States
(12) Patent Application Publication
(10) Pub. No.: US 2026/0328554 A1
(43) Pub. Date: Oct. 22, 2026

(54) METHOD FOR ADJUSTING A MAGNETIC SENSOR

(71) Applicant: COMPAGNIE GENERALE DES ETABLISSEMENTS MICHELIN, Clermont-Ferrand (FR)

(72) Inventor: OLIVIER LUDCHER, Clermont-Ferrand (FR)

(21) Appl. No.: 19/114,102

(22) PCT Filed: Sep. 22, 2023
(86) PCT No.: PCT/FR2023/051458

§ 371 Date: Mar. 21, 2025

(30) Foreign Application Priority Data
Sep. 23, 2022 (FR) FR2209683

(51) Int. Cl. G01B 7/06; B29D 30/54; G01R 33/00

(52) U.S. Cl. CPC G01B 7/102; B29D 30/54; G01R 33/0029; B29D 2030/546

(57) ABSTRACT

A method for adjusting a magnetic sensor (6) configured to supply, in the form of a response signal, a measurement of a distance separating the magnetic sensor (6) from a metal element (4) comprises: (a) acquiring a first raw response curve where the magnetic sensor (6) is successively placed in different positions so that the magnetic sensor (6) is successively at different corresponding distances from the metal element (4), and the response signal returned is collected in each of the positions, so as to obtain a raw response curve that shows the change in the response signal as a function of the distance separating the sensor from the metal element (4), (b) determining a correction curve model on the basis of the raw response curve, and a (c), determining a second corrected response curve by correcting the raw response curve on the basis of the correction curve model.

### FIELD OF THE INVENTION

The present invention relates to the field of recycling or retreading rubber-based objects and, more particularly, tyres. More specifically, the present invention relates to adjusting a magnetic sensor used for measuring a distance between a magnetic sensor and a metal element of a rubber-based object.

### PRIOR ART

A pneumatic tyre, more commonly referred to as a tyre, conventionally comprises a reinforcement ply, more specifically a reinforcement ply containing metal reinforcers embedded in a layer of coating rubber. This reinforcement ply is surrounded by a tread made from a rubber-based material.

During the retreading of a tyre, which aims to replace the worn tread with a new one, a so-called “buffing” step is carried out, consisting in machining (for example by grinding) the tyre in order to remove the tread from it. During this buffing step, the aim is to remove tread without coming into contact with the metal reinforcers of the reinforcement ply, in particular in order not to damage said reinforcement ply.

To perform buffing, it is therefore preferable to know the thickness of the residual tread in advance in order to accurately remove the tread thickness just necessary. In order to perform this tread thickness measurement, some suppliers of planing machines use magnetic sensors with analogue outputs. However, as the sensitivity setting of these sensors is fixed, the thickness measurements obtained can only remain reliable from one tyre to another if the tyres in question all have a similar density of metal reinforcers from one tyre to another. In fact, the inventors have observed that if an attempt is made to process tyres with different structures, which have substantial variations in the density of metal reinforcers from one tyre to another, significant measurement errors can occur.

There is therefore a need for a solution for accurately measuring the tread thickness remaining on a tyre.

### SUMMARY OF THE INVENTION

One aim of the invention is to accurately measure, using a magnetic sensor, the thickness of a rubber-based layer of an object also comprising a metal element.

Another aim of the invention is thus to allow automatic adjustment of the magnetic sensor suitable for different types of rubber-based object.

Another aim of the invention is to allow the efficient recycling or grinding of a rubber-based object also comprising a metal element.

According to a first aspect, a method is proposed for adjusting a magnetic sensor configured to supply, in the form of a response signal, a measurement of a distance separating said magnetic sensor from a metal element located in a rubber-based object, such as a metal reinforcing element present in a pneumatic tyre, said method comprising:
a step (a) of acquiring a first curve, referred to as the “raw response curve”, during which the sensor is successively placed in different positions relative to the object so that said sensor is successively at different corresponding distances from the metal element, and the response signal returned by said sensor is collected in each of said positions, so as to obtain raw response curve that shows the change in the response signal of the sensor as a function of the distance separating said sensor from the metal element,
a step (b) of determining a correction curve model on the basis of the raw response curve,
a correction step (c), during which a second curve, referred to as the “corrected response curve”, is determined by correcting the raw response curve on the basis of the correction curve model.

According to advantageous, non-limiting features, taken individually or in any combination:
the correction curve model is a standard response curve and, during step (b), on the basis of at least one characteristic of the raw response curve, the standard response curve is selected from a set of predetermined standard response curves that each represent, for a predefined particular metal element and object arrangement, the change in the response signal of the sensor as a function of the distance separating said sensor from the metal element of the particular arrangement under consideration;
during step (b), a point of inflection is identified on the raw response curve, the slope of the tangent to said raw response curve at this point of inflection is calculated, and the standard response curve that has a point of inflection the tangent of which has the slope closest to the slope calculated for the raw response curve is selected;
during step (b), coefficients of a polynomial regression of the raw response curve are compared with coefficients of polynomial regressions of the standard response curves, and the standard response curve the polynomial regression of which has coefficients that are closest to the coefficients of the polynomial regression of the raw response curve is selected;
during step (b), image processing is performed on the raw response curve and the standard response curves and the standard response curve having maximum similarity to the raw response curve is selected;
the standard response curve and/or the corrected response curve are expressed in the form of a fifth-degree polynomial function;
during the correction step (c), a reciprocal function of the standard response curve that was selected during step (b) of selecting a standard response curve is applied to the response signal of the raw response curve;
the standard response curves are determined on the basis of samples of objects in which the metal element the distance from the sensor of which is to be measured has been stripped, and by providing at least one distance measurement by the sensor in a position in which said sensor is in contact with said metal element, and therefore at zero actual distance from said metal element;
the standard response curves are determined by moving the sensor along an identical standardized trajectory relative to each object of one of the predefined arrangements, said standardized trajectory preferably being normal to a predefined reference portion of the surface of said object, and subsequently, during step (a) of acquiring the raw response curve, the successive positions of the sensor are situated on this same standardized trajectory;
during step (b), the correction curve model is constructed by extrapolation from points forming the raw response curve;
during step (b), the correction curve model is constructed by polynomial extrapolation from points forming the raw response curve;
during step (b), the correction curve model is constructed by symmetrizing the raw response curve relative to a point of inflection of the raw response curve;
during step (c), the distance value separating the sensor from the metal element corresponding to a zero response signal of the sensor is determined on the correction curve model and the raw response curve is shifted by this distance value;
during step (a), the sensor is moved from one position to another along a straight trajectory that follows a direction substantially normal to a selected portion of the surface of the object;
during step (a), the sensor is in contact with the surface of the object, at zero distance from said surface of the object, in one of the different positions that are successively occupied by said sensor;
during step (a), the positions successively occupied by the sensor are separated from each other by a predetermined pitch, preferably less than or equal to 1 mm, and more preferably less than or equal to 0.2 mm.

Advantageously, a method is proposed for adjusting a magnetic sensor configured to supply, in the form of a response signal, a measurement of a distance separating said magnetic sensor from a metal element located in a rubber-based object, such as a metal reinforcing element present in a pneumatic tyre, said method comprising:
a step (a) of acquiring a first curve, referred to as the “raw response curve”, during which the sensor is successively placed in different positions relative to the object so that said sensor is successively at different corresponding distances from the metal element, and the response signal returned by said sensor is collected in each of said positions, so as to obtain a raw response curve that shows the change in the response signal of the sensor as a function of the distance separating said sensor from the metal element,
   the method comprising, according to a first alternative:
a step (b) of determining a correction curve model on the basis of the raw response curve, the correction curve model being a standard response curve selected, on the basis of at least one characteristic of the raw response curve, from a set of predetermined standard response curves that each represent, for a predefined particular metal element and object arrangement, the change in the response signal of the sensor as a function of the distance separating said sensor from the metal element of the particular arrangement under consideration;
a correction step (c), in which a second curve referred to as the “corrected response curve” is determined, by correcting the raw response curve on the basis of the correction curve model by applying a reciprocal function of the standard response curve that was selected in step (b) of selecting a standard response curve to the response signal of the raw response curve, and
   the method comprising, according to a second alternative:
a step (b) of constructing a correction curve model by extrapolation from points forming the raw response curve;
a correction step (c), in which a second curve referred to as the “corrected response curve” is determined, by correcting the raw response curve on the basis of the correction curve model by determining on the correction curve model the distance value separating the sensor from the metal element corresponding to a zero response signal of the sensor and shifting the raw response curve by this distance value.

According to another aspect, a method is proposed for determining the actual distance separating a magnetic sensor from a metal element located in a rubber-based object, the magnetic sensor being configured to supply, in the form of a response signal, a measurement of a distance separating the magnetic sensor from the metal element comprising the steps of:
a) adjusting the magnetic sensor by implementing the adjustment method set out above on the object;
b) measuring a distance separating the magnetic sensor from the metal element in the form of a response signal;
c) correcting the distance measurement on the basis of the corrected response curve for obtaining the actual distance separating the magnetic sensor from the metal element.

According to another aspect, a method is proposed for calculating the distance separating a metal element from the surface of a rubber-based object in which the metal element is located, comprising steps of:
a) determining an actual distance value “A” between a magnetic sensor and the metal element by implementing the determination method set out above, the magnetic sensor being configured to supply, in the form of a response signal, a measurement of a distance separating the magnetic sensor from the metal element;
b) measuring, using a distance measuring system, the distance “B” between the distance measuring system and the surface of the object;
c) determining the distance “C” between the distance measuring system and the magnetic sensor;

### d) calculating the rubber thickness by calculating the formula A+B−C.

According to another aspect, a system is proposed for calculating the distance separating a metal element from the surface of a rubber-based object in which the metal element is located, said system comprising a magnetic sensor configured to measure a distance between the metal element and the magnetic sensor, a distance measuring system configured to measure a distance between the surface of the object and the distance measuring system and a data processing unit configured to implement the adjustment method set out above.

According to another aspect, a machining centre is proposed that is intended to remove rubber from a rubber-based object in which a metal element is located, said machining centre comprising a tool for machining the object, a control unit of the machining tool and the calculation system set out above, the control unit communicating with the calculation system in order to control the machining tool as a function of the calculated distance separating the metal element from the surface of the rubber-based object.

### DESCRIPTION OF THE FIGURES

Other features and advantages of the present invention will become apparent from reading the following description of a preferred embodiment. This description will be given with reference to the appended figures, in which:

FIG. 1 shows a system for adjusting a magnetic sensor;

FIG. 2 illustrates a raw response curve;

FIG. 3 illustrates standard response curves;

FIG. 4 shows a system for calculating the thickness of an outer layer of a rubber-based object;

FIG. 5 schematically shows a grinding machine comprising a system for adjusting a magnetic sensor and a system for calculating the thickness of an outer layer of a rubber-based object;

FIG. 6 shows the steps of the adjustment method;

FIG. 7 illustrates a correction curve model obtained by extrapolation;

FIG. 8 schematically shows a method for determining an actual distance separating a magnetic sensor from a metal element of a rubber-based object;

FIG. 9 schematically shows a method for shifting a correction curve model;

FIG. 10 shows the steps of a method for determining the actual distance separating a magnetic sensor from a metal element located in a rubber-based object;

FIG. 11 shows the steps of a method for calculating the distance separating a metal element from the surface of a rubber-based object.

### DETAILED DESCRIPTION OF THE INVENTION

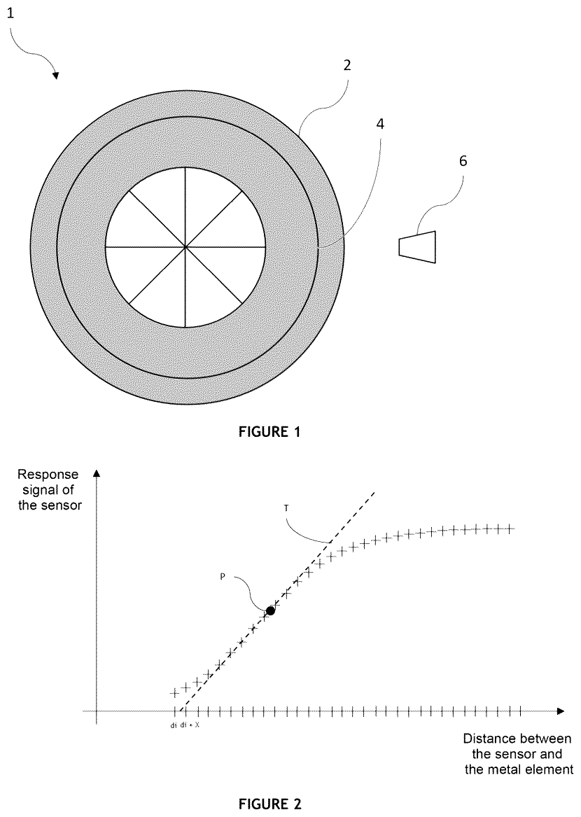

With reference to FIG. 1, a method is proposed for adjusting a magnetic sensor 6 intended to supply, in the form of a response signal, a measurement of a distance separating said magnetic sensor 6 from a metal element 4 located in a rubber-based object 1.

Preferably, the rubber-based object 1 is a pneumatic tyre and the metal element 4 is a reinforcer of the object 1 such as a metal ply forming the reinforcement of the pneumatic tyre. The object 1 can also be a track or a conveyor belt for a conveyor.

The magnetic sensor 6 is preferably a magnetic sensor with an analogue output.

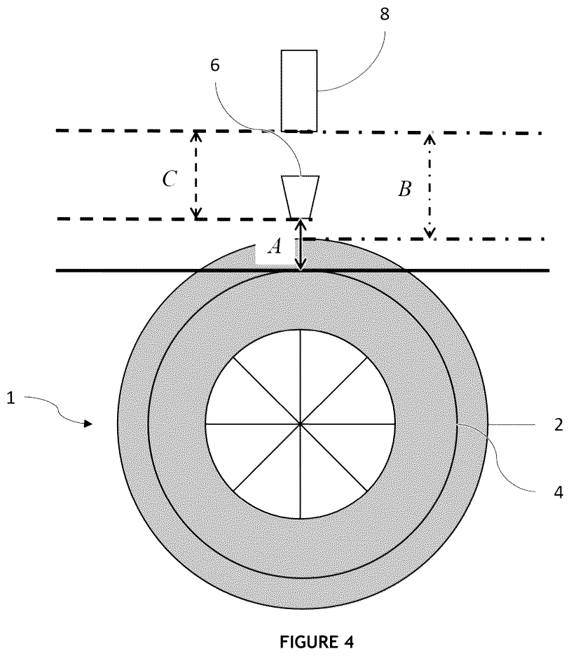

According to another aspect of the invention, with reference to FIG. 4, a system is proposed for calculating a thickness of an outer layer 2 of a rubber object 1 comprising a metal element 4. Advantageously, the calculation system makes it possible to calculate the rubber thickness of a pneumatic tyre.

The calculation system comprises a magnetic sensor 6 suitable for measuring a distance between the metal element 4 and the magnetic sensor and a distance measuring system 8, hereinafter referred to as the “auxiliary distance measuring system 8”, suitable for measuring a distance between the outer layer 2 of the rubber-based object 1 and the auxiliary distance measuring system 8. The calculation system further comprises a data processing unit configured to implement the method for adjusting the magnetic sensor 6.

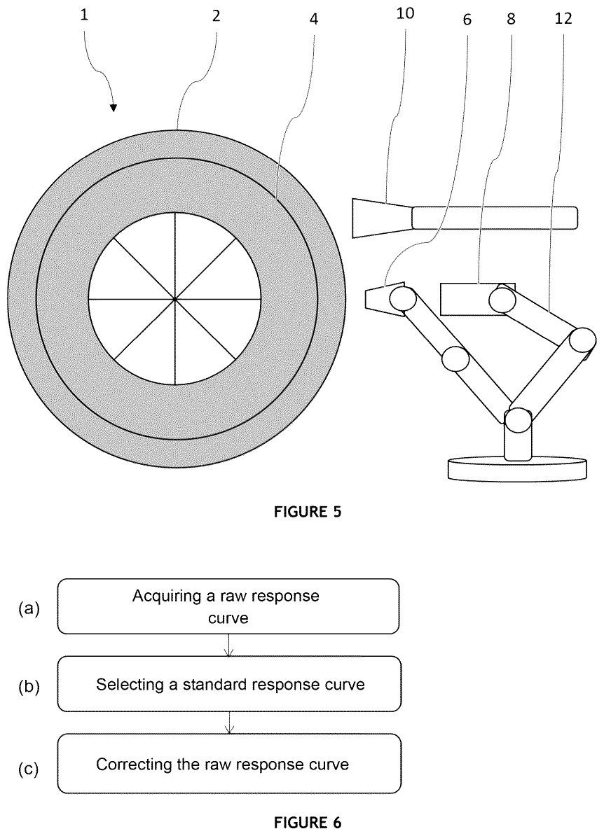

As illustrated in FIG. 5, the magnetic sensor 6 and the auxiliary distance measuring system 8 can be held by a robotic arm 12. The magnetic sensor 6 and the auxiliary distance measuring system 8 can thus be moved by means of the robotic arm 12.

The auxiliary distance measuring system 8 is typically a laser measuring system.

According to another aspect of the invention, with reference to FIG. 5, a machining centre is proposed for machining a rubber-based object 1, comprising a tool 10 for machining the outer layer of the object, a control unit of the machining tool 10 and the system for calculating the thickness of the outer layer. The control unit is configured to communicate with the calculation system in order to control the machining tool 10 as a function of the calculated thickness of the outer layer.

Advantageously, the machine is a machine for buffing a pneumatic tyre and makes it possible to perform the buffing step as part of a process of recycling or retreading the pneumatic tyre.

It will be understood that the calculation system makes it possible to know the thickness of the tread remaining on the pneumatic tyre. This calculated thickness makes it possible to accurately determine the tread thickness to be buffed away. For recycling, the control unit will control the machining tool to buff the tread until there is very little tread left on the metal element, preferably 2 mm of tread. For retreading, the control unit will control the machining tool to buff the tread until there is a little more tread left than for recycling, preferably 5.5 mm of tread.

### Methods

A method is proposed for adjusting a magnetic sensor intended to supply, in the form of a response signal, a measurement of a distance separating the magnetic sensor from a metal element located in a rubber-based object with a view to calculating the thickness of an outer layer of the rubber-based object. As explained above, the metal element is different from object to another and can therefore have different characteristics. This is because, from one object to another, the material forming the metal element can differ (and therefore the density, composition, magnetic permeability, etc.), the quantity (and therefore the mass) of the metal element in the object can differ, and the arrangement (and therefore the shape, distribution, depth, etc.) of the metal element in the object can also differ. As a result, a single adjustment of the magnetic sensor cannot make it possible to take correct measurements. In order to accurately measure the distance between the magnetic sensor and the metal element, the magnetic sensor must be adjusted so that it is suitable for the metal element and, more generally, for each object to be processed.

However, the exact characteristics of the metal element and more generally of the object are not necessarily known at the time when a thickness of rubber is to be removed from the object by machining. In the case of a pneumatic tyre for example, the metal element is inside the tyre and is not visible. Sometimes, it is not possible to know the characteristics of the metal element. However, it is still necessary to adjust the magnetic sensor to suit the metal element. The method disclosed improves this situation.

With reference to FIG. 6, the method comprises a step a) of acquiring a first curve, referred to as the “raw response curve”. To this end, the magnetic sensor is positioned facing the object. For a pneumatic tyre, the magnetic sensor is positioned facing the tread.

During step a), the magnetic sensor is successively placed in different positions relative to the object so that the sensor is successively located at different corresponding distances from the metal element. Preferably, the magnetic sensor is moved from one position to another along a straight trajectory that follows a direction substantially normal to a selected portion of the surface of the object. In other words, for a pneumatic tyre, the magnetic sensor is advantageously moved radially to the pneumatic tyre. The magnetic sensor can be moved manually. Preferably, the magnetic sensor is moved mechanically by a robotic arm. Conversely, the magnetic sensor could be fixed and the object could be moved relative to the sensor.

Preferably, the magnetic sensor is initially in contact with the surface of the object and therefore in contact with the outer surface of the outer layer of the object. In other words, the magnetic sensor is at zero distance from the surface of the object. The magnetic sensor is then gradually moved away from the surface of the object. According to a converse embodiment, the magnetic sensor is initially separated from the surface of the object and is then gradually moved towards the surface of the object until it reaches a position in which the magnetic sensor is in contact with the surface of the object. This has the advantage of ensuring that a sufficiently large distance range between the magnetic sensor and the metal element is travelled so that it actually contains a point of inflection of the raw response curve. The benefit of this will be understood on reading the rest of the present description. Typically, said distance range is of the order of 1 mm to 30 mm.

In addition, in each of the positions of the magnetic sensor, the data processing unit collects the response signal returned by the magnetic sensor so as to obtain the raw response curve, which shows the change in the response signal of the magnetic sensor as a function of the distance separating the sensor from the metal element. FIG. 2 illustrates a raw response curve. The ordinates correspond to the response signal of the magnetic sensor and the abscissas correspond to the distance separating the sensor from the metal element. It will be understood that the absolute value of the abscissas is not known as the actual distance between the magnetic sensor and the metal element is not known at this stage of the method. Each graduation on the abscissa axis corresponds to an initial distance di+X. The initial distance di is an unknown distance separating the magnetic sensor from the metal element for the first measurement performed by the magnetic sensor on the object under consideration. X corresponds to the difference between the initial distance and the distance separating the magnetic sensor from the metal element for another measurement performed by the magnetic sensor on the object in question. In fact, X preferably corresponds to a multiple of a pitch by which the magnetic sensor is advantageously moved between each successive measurement by the magnetic sensor. In addition, preferably, the positions successively occupied by the sensor are separated from each other by a predetermined pitch, preferably less than or equal to 1 mm, and more preferably less than or equal to 0.2 mm.

In a so-called determination step (b), a correction curve model is determined on the basis of the raw response curve. The correction curve model is a model typically in the form of a curve. The correction curve model preferably shows the change in a response signal of a magnetic sensor as a function of the distance separating the sensor from a metal element. The correction curve model is intended to make it possible to correct the raw response curve, as described below. The correction curve model can be determined according to different embodiments.

According to a first so-called standard embodiment, the correction curve model is a standard response curve and step b) comprises selecting a standard response curve. More specifically, on the basis of at least one characteristic of the raw response curve, a standard response curve is selected from a set of predetermined standard response curves.

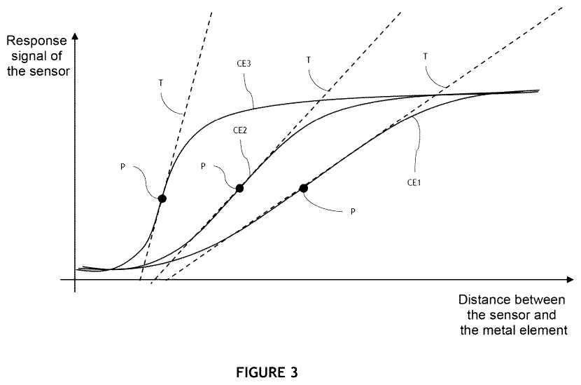

The predetermined standard response curves each represent, for a particular predefined metal element and object arrangement, the change in the response signal of the magnetic sensor as a function of the distance separating the magnetic sensor from the metal element of the particular arrangement under consideration. Standard response curves, together with their points of inflection P and their tangents T to their points of inflection, are illustrated in FIG. 3. The particular metal element and object arrangement encompasses, inter alia, the type of metal element and the type of object, and therefore the intrinsic characteristics of the metal element and the object. For example, FIG. 3 shows a set of three standard response curves CE1, CE2 and CE3, which respectively characterize a first object O1, a second object O2 and a third object O3, which each correspond to a pneumatic tyre, but which differ from each other in the arrangement of the reinforcers that are present in their reinforcement plies and that form the metal elements, here made from steel. By way of non-limiting example, the first object O1, characterized by the first standard response curve CE1, can correspond to a pneumatic tyre a reinforcement ply of which has metal reinforcers that are thicker and/or closer to each other, and therefore a denser network of metal elements than the network of the corresponding elements of the second object O2 characterized by the second standard response curve CE2, which second object O2 in turn has a denser network of metal elements than the third object O3 characterized by the third standard response curve CE3. Each predetermined standard response curve thus relates to a predefined particular arrangement.

Preferably, each standard response curve has been determined in advance (i.e. preferably prior to step a)) on the basis of samples of objects in which the metal element the distance of which relative to the sensor is to be measured has been stripped. In other words, the standard response curves are determined on the basis of samples of objects from which the outer layer of rubber initially covering the metal element has been removed, in order to expose said metal element, which makes it possible to know the exact physical distance separating the magnetic sensor from the metal element. As a result, the standard response curves show the change in the response signal of the sensor as a function of the distance separating the magnetic sensor from the metal element, said distance being known. The actual values of the abscissas of the standard response curves are thus known, with respect to a known reference, which can be considered to be an absolute origin of the abscissa axis, which is embodied by the stripped metal element. As a result, for each measurement of the distance separating the magnetic sensor from the metal element, the actual distance separating the magnetic sensor from the metal element is known.

Preferably, each standard response curve has been determined in advance so that for at least one distance measurement by the magnetic sensor, the magnetic sensor is in a position in which it is in contact with the metal element, and therefore at zero actual distance from the metal element. This has the advantage of ensuring that a sufficiently large distance range between the magnetic sensor and the metal element is travelled so that it actually contains the point of inflection of the standard response curve. The benefit of this will be understood on reading the rest of the present description. In addition, this means that the standard response curves cover the entire usable range of measurement, which then makes it possible to remove the outer layer to as close as possible to the metal element. “Usable range of measurement” is given to mean a distance range between the metal element and the magnetic sensor extending at least between a zero distance (the magnetic sensor is in contact with the metal element) and the distance equal to the initial thickness of the outer layer of the object. In order to estimate the thickness of the remaining outer layer dynamically, as machining is taking place, in order to machine to as close as possible to the metal element but with a sufficient safety margin, the sensor must be capable of estimating the thicknesses situated in this usable measurement range.

Preferably, the standard response curves are expressed in the form of a third-or fifth-degree polynomial function. Advantageously, the standard response curves are expressed in the form of a fifth-degree polynomial function as this guarantees the existence of a non-constant, non-zero (third-degree) second derivative. This function will thus necessarily have at least one root (which can also be calculated using an exact formula), which guarantees that the function, and therefore the standard response curve, has a point of inflection at this function.

Also preferably, the same magnetic sensor is used for producing the standard response curves according to the different predefined metal element and object arrangements and for step (a) of acquiring the raw response curve. To this end, either, according to a first possible embodiment, a first magnetic sensor can be used to produce the standard response curves and then a second magnetic sensor can be used to acquire the raw response curve, the first magnetic sensor being the same model (and therefore having the same operating specifications) as the second magnetic sensor, or, according to a second possible embodiment, one and the same magnetic sensor can physically be used firstly to produce the standard response curves and subsequently to acquire the raw response curve. It will thus be understood that the adjustment of the magnetic sensor is performed on the basis of standard response curves perfectly suited to said magnetic sensor. The method will therefore be particularly reliable.

Ideally, the standard response curves are determined by moving the magnetic sensor along an identical standardized trajectory relative to each object of one of the predefined arrangements and the standardized trajectory is preferably normal to a predefined reference portion of the surface of the object. In addition, ideally, during step (a) of acquiring a raw response curve, the successive positions of the sensor are situated on this same standardized trajectory. The raw response curves and the standard response curves are thus obtained in comparable conditions, and are thus easy to compare with each other, in particular when it comes to determining which standard response curve to link the raw response curve to in order to obtain the corrected response curve, for example by identifying which standard response curve best overlays the raw response curve. The method is thus reliable, simple and repeatable. For example, for a pneumatic tyre, the standardized trajectory can be a radial trajectory moving away from the outer surface of the tread of the pneumatic tyre. By way of a second example, the trajectory can also be substantially radial such as for example contained in a cone having an axis normal to the outer surface of the outer layer of the object and an apex angle less than or equal to 5 degrees, preferably less than or equal to 2 degrees.

Advantageously, during step (b), in order to select a standard response curve, a point of inflection P is identified on the raw response curve by the data processing unit. By definition, in mathematics, a point of inflection is a point at which a change in concavity of a plane curve takes place. At such a point, the tangent T passes through the curve. A point of inflection of the raw response curve (as well as the tangent to the curve at this point) is for example illustrated in FIG. 2. The point of inflection can be determined in different ways. A first way is to calculate the second derivative of the raw response curve in order to identify the point at which this second derivative is cancelled. Then, the first derivative is calculated at this point, which corresponds to the point of inflection. A second way is to consider that the point of inflection is always located in the middle of the range of measurements of the raw response curve. More specifically, “middle of the range of measurements of the raw response curve” is given to mean that the point of inflection is half way up the range covered by all of the measurement signals returned by the sensor and collected during the acquisition a) of the raw response curve in the different positions successively occupied by said sensor.

Next, the slope of the tangent to said raw response curve at this point of inflection is calculated. The standard response curve selected is the one that has a point of inflection the tangent T of which has the slope closest to the slope calculated for the raw response curve. “Closest” is given to mean that the difference between the slope calculated for the standard response curve selected and the slope calculated for the raw response curve is minimal.

According to another embodiment, step b) of selecting a standard response curve is performed by comparing the coefficients of a polynomial regression of the raw response curve with the coefficients of polynomial regressions of the standard response curves. More specifically, a polynomial regression, for example fifth-degree, is calculated for the raw response curve and the standard response curves. The coefficients of the regression of the raw response curve are then compared to the coefficients of the standard response curves. The standard response curve the regression of which has coefficients that are closest to the regression coefficients of the raw response curve is thus selected. Different techniques can be used to determine which is the standard response curve the regression of which has coefficients that are closest to the coefficients of the regression of the raw response curve.

According to yet another embodiment, step b) of selecting a standard response curve is performed by image processing. More specifically, the image processing is applied to identify which is the standard response curve with which the raw response curve has maximum similarity.

In fact, step b) consists in identifying the standard response curve closest to the raw response curve. This is because it is considered that the particular metal element and object arrangement corresponding to the raw response curve probably corresponds to the particular metal element and object arrangement corresponding to the standard response curve that is identified as being closest to the raw response curve. The aim is to be able to use the known data from the standard response curve to estimate a distance separating the metal element from the magnetic sensor (with which the raw response curve was obtained).

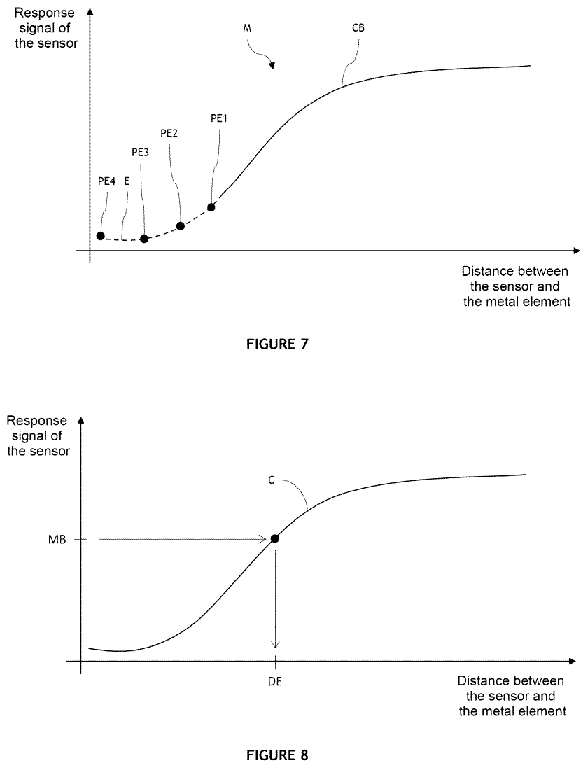

According to a second so-called extrapolation embodiment illustrated in FIG. 7, the correction curve model is constructed by extrapolation from points forming the raw response curve. It will therefore be understood that the correction curve model is formed by the points of the raw response curve and by points determined by extrapolation. The extrapolation can be performed by various means. In the example illustrated in FIG. 7, the correction curve model M is constructed from the raw response curve CB (plotted as a solid line). Points PE1, PE2, PE3 and PE4 are obtained by extrapolation and form an extrapolation curve E (plotted as a dashed line). The assembly formed by the raw response curve CB and the extrapolation curve E forms the correction curve model M.

For example, the extrapolation performed is a polynomial extrapolation so that the correction curve model can be expressed in the form of a polynomial. Advantageously, the correction curve model can be expressed in the form of a fifth-degree polynomial.

Alternatively, the extrapolation is a symmetrization. More specifically, the correction curve model is constructed by symmetrizing the raw response curve relative to a point of inflection of the raw response curve.

Next, in a so-called correction step c), a second curve, referred to as the “corrected response curve”, is determined by correcting the raw response curve on the basis of the correction curve model.

According to the standard embodiment, step c) consists in correcting the raw response curve on the basis of the standard response curve selected. More specifically, a reciprocal function of the standard response curve selected is applied to the response signal of the raw response curve.

With reference to FIG. 8, this consists in determining, on the standard response curve C, for one or more measurement values of the raw response curve returned by the magnetic sensor, which abscissa value DE (and therefore which actual distance DE separating the magnetic sensor from the metal element) the image having the raw measurement value MB returned by the magnetic sensor corresponds to. In other words, for a certain raw measurement value MB returned by the magnetic sensor, the abscissa value DE on the standard response curve, and therefore the actual distance separating the magnetic sensor from the metal element, to which this raw measurement value corresponds, is determined. The corrected response curve is thus constructed by correcting points of the raw response curve as a function of the standard response curve selected.

Next, step c) preferably comprises a step of obtaining a continuous corrected response curve. In other words, step c) preferably comprises a step of connecting the determined points of the corrected response curve and therefore determining the missing points of the corrected response curve.

To this end, according to one embodiment, a polynomial interpolation, preferably third-or fifth-degree, is performed on the points of the corrected response curve. The complete corrected response curve is thus obtained. The data processing unit is therefore preferably configured to perform this type of interpolation.

According to another embodiment, particularly if the data processing unit is not configured to perform third-or fifth-degree interpolations, a so-called “segment by segment” method is used. More specifically, a straight-line interpolation is performed between two points of the corrected response curve, preferably two consecutive abscissa points. The straight-line interpolation is preferably performed several times so as to connect together a set of points of the corrected response curve.

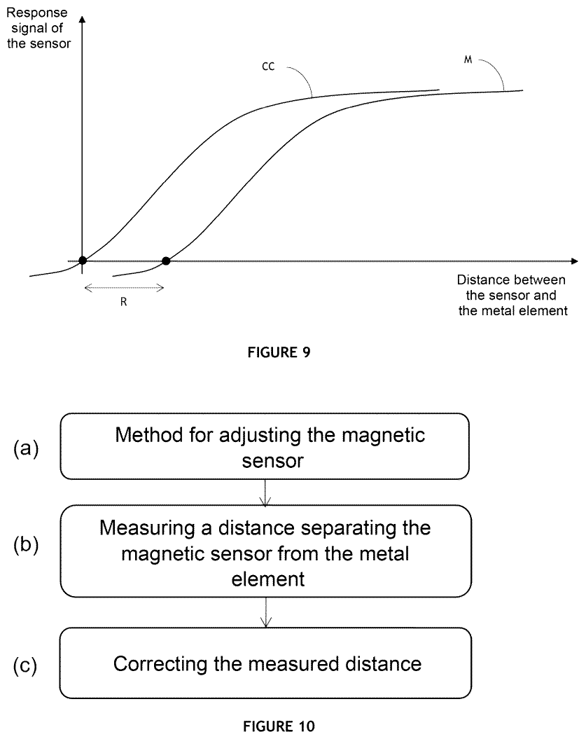

According to the extrapolation embodiment, in step c), the correction curve model is shifted. More specifically, with reference to FIG. 9, the distance value R separating the sensor from the metal element corresponding to a zero response signal of the sensor is first determined on the correction curve model M. In other words, which abscissa the correction curve model intersects the abscissa axis at is determined. Then, the correction curve model is offset by the abscissa value R determined so that the point of the curve that corresponded to a zero ordinate has a zero abscissa. The raw response curve is thus replaced by the shifted correction curve model. The corrected response curve CC is thus obtained.

Finally, it will be understood that the corrected response curve CC corresponds to the raw response curve to which an extrapolation has been applied (to give the correction curve model) and to which a shift has been applied.

At the end of step c), the magnetic sensor has been adjusted. The method therefore allows automatic self-adjustment of the magnetic sensor that is suitable for any type of rubber-based object and therefore, for example more particularly, for any type of pneumatic tyre. Actual distance values between the magnetic sensor and the metal element can thus be obtained as a function of the positions of the magnetic sensor vis-à-vis the object.

With reference to FIG. 10, in this regard a method is proposed for determining the actual distance separating the magnetic sensor from the metal element comprising a step a) of adjusting the magnetic sensor as described above.

Then, in a step b), a distance separating the magnetic sensor from the metal element is measured by the magnetic sensor.

Finally, in a step c), the distance measured is corrected on the basis of the corrected response curve and an actual distance separating the magnetic sensor from the metal element is obtained. More specifically, which abscissa the distance measured on the corrected response curve corresponds to is sought. The abscissa defined corresponds to the actual distance.

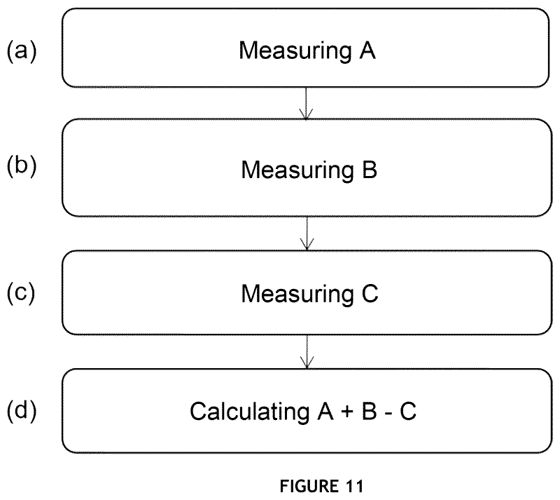

The actual distance value obtained makes it possible to calculate the distance separating the metal element from the surface of the rubber-based object and therefore the thickness of the outer layer of the object, typically the thickness of the tread in the case of a pneumatic tyre. In this regard, with reference to FIGS. 4 and 11, a method is proposed for calculating the distance separating the metal element 4 from the surface of the rubber-based object 1 in which the metal element 4 is located, firstly comprising a step a) of determining an actual distance value A between the magnetic sensor 6 and the metal element 4 as explained above.

Next, the calculation method comprises a step b) of measuring, using the auxiliary distance measuring system 8, the distance B between the auxiliary measuring system 8 and the object 1. In addition, in a step c), the distance C between the auxiliary distance measuring system 8 and the magnetic sensor 6 is determined. More specifically, the distance C corresponds to the distance between a distal point of the auxiliary distance measuring system 8 and a distal point of the magnetic sensor 6. Furthermore, the step c) can simply be performed by manual measurement or preferably by automatic calculation, if the auxiliary distance measuring system 8 and the magnetic sensor 6 are positioned on robotic arms the positioning of which is known and adjustable.

Finally, in step d), the distance separating the metal element 4 from the surface of the object 1 is calculated using the formula A+B−C. As a result, the thickness of the outer layer 2 of the object 1 that must be machined can be determined and controlled without the machining tool 10 reaching the metal element 4, which could damage the metal element 4 and the tool 10.

According to another embodiment, there is no need to use an auxiliary distance measuring system 8 to determine the actual distance separating the metal element 4 from the surface of the object 1. According to this embodiment, a distance separating the magnetic sensor 6 from the metal element 4 is measured by the magnetic sensor 6 when the magnetic sensor 6 is occupying the position in contact with the surface of the object 1. Next, the distance measured is corrected on the basis of the corrected response curve and the actual distance separating the magnetic sensor 6 from the metal element 4 and therefore the actual distance separating the metal element 4 from the surface of the object 1 are obtained (these distances being the same given that the magnetic sensor 6 is occupying the position in contact with the surface of the object 1).

The invention is not limited to the embodiment described and shown in the appended figures. Modifications are possible, in particular from the point of view of the composition of the various technical features or by substituting technical equivalents, without however departing from the general scope of the invention.

1.-20. (canceled)

21. A method for adjusting a magnetic sensor configured to supply, in a form of a response signal, a measurement of a distance separating the magnetic sensor from a metal element located in a rubber-based object, the method comprising the following steps:
(a) acquiring a raw response curve, during which the magnetic sensor is successively placed in different positions relative to the rubber-based object so that the magnetic sensor is successively at different corresponding distances from the metal element, and the response signal returned by the magnetic sensor is collected in each of the different positions, so as to obtain the raw response curve that shows a change in the response signal of the magnetic sensor as a function of the distance separating the magnetic sensor from the metal element;
(b) determining a correction curve model on a basis of the raw response curve; and
(c) determining a corrected response curve by correcting the raw response curve on a basis of the correction curve model.

22. The method according to claim 21, wherein the correction curve model is a standard response curve and, during step (b), on a basis of at least one characteristic of the raw response curve, the standard response curve is selected from a set of predetermined standard response curves that each represent, for a predefined particular metal element and rubber-based object arrangement, a change in the response signal of the magnetic sensor as a function of the distance separating the magnetic sensor from the metal element of the particular metal element and rubber-based object arrangement.

23. The method according to claim 22, wherein, during step (b), a point of inflection is identified on the raw response curve, a slope of a tangent to the raw response curve at the point of inflection is calculated, and the standard response curve that has a point of inflection a tangent of which has a slope closest to the slope calculated for the raw response curve is selected.

24. The method according to claim 22, wherein, during step (b), coefficients of a polynomial regression of the raw response curve are compared with coefficients of polynomial regressions of the standard response curves, and the standard response curve the polynomial regression of which has coefficients that are closest to the coefficients of the polynomial regression of the raw response curve is selected.

25. The method according to claim 22, wherein, during step (b), image processing is performed on the raw response curve and the standard response curves and the standard response curve having a maximum similarity to the raw response curve is selected.

26. The method according to claim 22, wherein the standard response curve or the corrected response curve or both the standard response curve and the corrected response curve are expressed as a fifth-degree polynomial function.

27. The method according to claim 22, wherein, during step (c), a reciprocal function of the standard response curve that was selected during step (b) is applied to the response signal of the raw response curve.

28. The method according to claim 22, wherein the standard response curves are determined on a basis of samples of rubber-based objects in which the metal element the distance from the magnetic sensor of which is to be measured has been stripped, and by providing at least one distance measurement by the magnetic sensor in a position in which the magnetic sensor is in contact with the metal element, and therefore at zero actual distance from the metal element.

29. The method according to claim 22, wherein the standard response curves are determined by moving the magnetic sensor along an identical standardized trajectory relative to each rubber-based object of one of the predefined metal element and rubber-based object arrangements, and wherein, subsequently, during step (a), the successive positions of the magnetic sensor are situated on the identical standardized trajectory.

30. The method according to claim 21, wherein, during step (b), the correction curve model is constructed by extrapolation from points forming the raw response curve.

31. The method according to claim 30, wherein, during step (b), the correction curve model is constructed by polynomial extrapolation from points forming the raw response curve.

32. The method according to claim 31, wherein, during step (b), the correction curve model is constructed by symmetrizing the raw response curve relative to a point of inflection of the raw response curve.

33. The method according to claim 30, wherein, during step (c), a distance value separating the magnetic sensor from the metal element corresponding to a zero response signal of the magnetic sensor is determined on the correction curve model and the correction curve model is shifted by the distance value.

34. The method according to claim 21, wherein, during step (a), the magnetic sensor is moved from one position to another along a straight trajectory that follows a direction normal to a selected portion of a surface of the rubber-based object.

35. The method according to claim 21, wherein, during step (a), the magnetic sensor is in contact with a surface of the rubber-based object, at zero distance from the surface of the rubber-based object, in one of the different positions that are successively occupied by the magnetic sensor.

36. The method according to claim 21, wherein, during step (a), the positions successively occupied by the magnetic sensor are separated from each other by a predetermined pitch.

37. A method for determining an actual distance separating a magnetic sensor from a metal element located in a rubber-based object, the magnetic sensor being configured to supply, as a response signal, a measurement of a distance separating the magnetic sensor from the metal element comprising:
(a) adjusting the magnetic sensor by implementing the method according to claim 21 on the rubber-based object;
(b) measuring a distance separating the magnetic sensor from the metal element in the form of a response signal; and
(c) correcting the distance measurement on a basis of the corrected response curve for obtaining the actual distance separating the magnetic sensor from the metal element.

38. A method for calculating a distance separating a metal element from a surface of a rubber-based object in which the metal element is located, the method comprising:
(a) determining the actual distance value A between a magnetic sensor and the metal element by implementing the method according to claim 37, the magnetic sensor being configured to supply, as a response signal, a measurement of a distance separating the magnetic sensor from the metal element;
(b) measuring, by a distance measuring system, a distance B between the distance measuring system and the surface of the rubber-based object;
(c) determining a distance C between the distance measuring system and the magnetic sensor; and
(d) calculating a rubber thickness by calculating a formula A+B−C.

39. A system for calculating a distance separating a metal element from a surface of a rubber-based object in which the metal element is located, the system comprising a magnetic sensor configured to measure a distance between the metal element and the magnetic sensor, a distance measuring system configured to measure a distance between the surface of the rubber-based object and the distance measuring system and a data processing unit configured to implement the method according to claim 21.

40. A machining center intended to remove rubber from a rubber-based object in which a metal element is located, the machining center comprising a machining tool for machining the rubber-based object, a control unit of the machining tool and the system according to claim 39, the control unit communicating with the system in order to control the machining tool as a function of the calculated distance separating the metal element from the surface of the rubber-based object.
